(19) United States
(12) Patent Application Publication
(10) Pub. No.: US 2019/0013347 A1
(43) Pub. Date: Jan. 10, 2019

(54) SEMICONDUCTOR DEVICE AND METHOD OF MANUFACTURING SEMICONDUCTOR DEVICE

(71) Applicant: OLYMPUS CORPORATION, Tokyo (JP)

(72) Inventor: Kenji Kobayashi, Tokyo (JP)

(73) Assignee: OLYMPUS CORPORATION, Tokyo (JP)

(21) Appl. No.: 16/129,072

(22) Filed: Sep. 12, 2018

Related U.S. Application Data
(63) Continuation of application No. PCT/JP2016/061533, filed on Apr. 8, 2016.

(51) Int. Cl. H01L 27/146; H01L 23/00

(52) U.S. Cl. CPC H01L 27/14636; H01L 24/17; H01L 2924/3025; H01L 27/14612; H01L 27/14634

(57) ABSTRACT

A semiconductor device includes a first semiconductor substrate, a second semiconductor substrate, a plurality of connectors, a first insulating part, and a shielding part. The second semiconductor substrate is laminated on the first semiconductor substrate. The plurality of connectors are disposed between the first semiconductor substrate and the second semiconductor substrate and electrically connect a first circuit and a second circuit. The first insulating part is disposed around each of connectors included in the plurality of connectors. The shielding part is disposed inside of the first insulating part and formed of a conductor. A void is provided between the connectors and the first insulating part.

The present application is a continuation application based on international patent application PCT/JP 2016/061533, filed on Apr. 8, 2016, the content of which is incorporated herein by reference.

### BACKGROUND OF THE INVENTION

### Field of the Invention

The present invention relates to a semiconductor device and a method of manufacturing a semiconductor device.

### Description of Related Art

Laminated structures for a semiconductor chip suitable for miniaturization of semiconductor devices have attracted attention. For example, an imager disclosed in Japanese Patent No. 4349232 includes a plurality of laminated substrates and has a pixel array disposed on substantially the entire surface of a first substrate. Recently, further miniaturization of semiconductor chips has been required due to demand for miniaturization of electronic apparatuses.

There are two requirements for laminated semiconductor chips.

First requirement: Bumps (connectors) which connect two semiconductor substrates should be finely formed. Bumps should be arranged at a high density. Short-circuiting of bumps due to collapsing thereof or damage thereto should not occur when two semiconductor substrates are bonded to each other.

Second requirement: Noise caused by a circuit disposed on a second semiconductor substrate should not be superimposed on a signal output from a first semiconductor substrate. For example, noise caused by a circuit disposed on the second substrate should not be superimposed on a signal output from a photoelectric converter disposed on the first semiconductor substrate in a laminated imager.

With respect to the two above-described requirements, technologies disclosed in Japanese Unexamined Patent Application, First Publication No. H6-236981 and Japanese Unexamined Patent Application, First Publication No. 2015-60909 have attempted to seek solutions. Japanese Unexamined Patent Application, First Publication No. H6-236981 discloses a technology for the first requirement. In the technology disclosed in Japanese Unexamined Patent Application, First Publication No. H6-236981, an insulator is disposed between bumps to avoid short-circuiting between the bumps. In the technology disclosed in Japanese Unexamined Patent Application, First Publication No. 2015-60909, a conductor is disposed between two substrates. Accordingly, superimposition of noise caused by a circuit disposed on the second semiconductor substrate on a signal output from the first semiconductor substrate is avoided.

### SUMMARY OF THE INVENTION

According to a first aspect embodiment of the present invention, a semiconductor device includes a first semiconductor substrate, a second semiconductor substrate, a plurality of connectors, a first insulating part, and a shielding part. The first semiconductor substrate includes a first circuit. The second semiconductor substrate is laminated on the first semiconductor substrate and includes a second circuit. The plurality of connectors are disposed between the first semiconductor substrate and the second semiconductor substrate and electrically connect the first circuit and the second circuit. The first insulating part is disposed around each of connectors included in the plurality of connectors. The shielding part is disposed inside of the first insulating part and formed of a conductor. A void is provided between the connectors and the first insulating part.

According to a second aspect of the present invention, in the first aspect, the shielding part may be electrically insulated from all of the first semiconductor substrate, the second semiconductor substrate, and the plurality of connectors.

According to a third aspect of the present invention, in the first aspect, the shielding part may be electrically connected to only any one of the first semiconductor substrate and the second semiconductor substrate. The shielding part may be connected to a fixed potential in the first semiconductor substrate or the second semiconductor substrate to which the shielding part is connected.

According to a fourth aspect of the present invention, in any one of the first to third aspects, the semiconductor device may further include a plurality of first insulating parts including the first insulating part and a plurality of shielding parts including the shielding part. Gaps may be provided between the plurality of first insulating parts. Gaps may be provided between each of first insulating parts included in the plurality of first insulating parts and each of the connectors.

According to a fifth aspect of the present invention, in the fourth aspect, two or more of the first insulating parts and two or more of the shielding parts may be disposed corresponding to each of the connectors.

According to a sixth aspect of the present invention, in any one of the first to fifth aspects, the shielding part may be electrically connected to only the first semiconductor substrate. Gaps may be provided between the second semiconductor substrate and the first insulating part.

According to a seventh aspect of the present invention, in any one of the first to sixth aspects, the connectors may be formed of a first material. The shielding part may be formed of a second material different from the first material.

According to an eighth aspect of the present invention, in any one of the first to seventh aspects, the thickness of the shielding part in a direction perpendicular to a lamination direction of the first semiconductor substrate and the second semiconductor substrate may be less than the thickness of the connectors in the direction.

According to a ninth aspect of the present invention, a method of manufacturing a semiconductor device includes a first process, a second process, and a third process. A first insulating part is formed around a first region in which each of a plurality of connectors are to be disposed on a first principal plane of a first semiconductor substrate and a shielding part is formed inside of the first insulating part through the first process. The first semiconductor substrate includes a first circuit. The shielding part is formed of a conductor. The plurality of connectors are formed in a second region corresponding to the first region on a second principal plane of a second semiconductor substrate through the second process. The second semiconductor substrate includes a second circuit. The first semiconductor substrate and the second semiconductor substrate are bonded in a state in which the first principal plane and the second principal plane face each other, and a void is provided between connectors included in the plurality of connectors and the first insulating part through the third process. The plurality of connectors are electrically connected to the first circuit and the second circuit.

According to a tenth aspect of the present invention, in the ninth aspect, the method of manufacturing a semiconductor device may further include a fourth process of filling the void with an insulating resin after the first semiconductor substrate and the second semiconductor substrate are bonded.

### BRIEF DESCRIPTION OF THE DRAWINGS

FIG. 1 is a cross-sectional view of a semiconductor device according to a first embodiment of the present invention.

FIG. 2 is a cross-sectional view of the semiconductor device according to the first embodiment of the present invention.

FIG. 3 is a block diagram showing a configuration of a first substrate according to the first embodiment of the present invention.

FIG. 4 is a block diagram showing a configuration of a second substrate according to the first embodiment of the present invention.

FIG. 5 is a cross-sectional view for describing a method of manufacturing the semiconductor device according to the first embodiment of the present invention.

FIG. 6 is a cross-sectional view for describing the method of manufacturing the semiconductor device according to the first embodiment of the present invention.

FIG. 7 is a cross-sectional view for describing the method of manufacturing the semiconductor device according to the first embodiment of the present invention.

FIG. 8 is a cross-sectional view for describing the method of manufacturing the semiconductor device according to the first embodiment of the present invention.

FIG. 9 is a cross-sectional view for describing the method of manufacturing the semiconductor device according to the first embodiment of the present invention.

FIG. 10 is a cross-sectional view for describing the method of manufacturing the semiconductor device according to the first embodiment of the present invention.

FIG. 11 is a cross-sectional view for describing the method of manufacturing the semiconductor device according to the first embodiment of the present invention.

FIG. 12 is a cross-sectional view for describing the method of manufacturing the semiconductor device according to the first embodiment of the present invention.

FIG. 13 is a cross-sectional view for describing the method of manufacturing the semiconductor device according to the first embodiment of the present invention.

FIG. 14 is a cross-sectional view of a semiconductor device according to a modified example of the first embodiment of the present invention.

FIG. 15 is a cross-sectional view of the semiconductor device according to the modified example of the first embodiment of the present invention.

FIG. 16 is a cross-sectional view of a semiconductor device according to a second embodiment of the present invention.

FIG. 17 is a cross-sectional view of a semiconductor device according to a third embodiment of the present invention.

### DETAILED DESCRIPTION OF THE INVENTION

Embodiments of the present invention will be described with reference to the drawings.

### First Embodiment

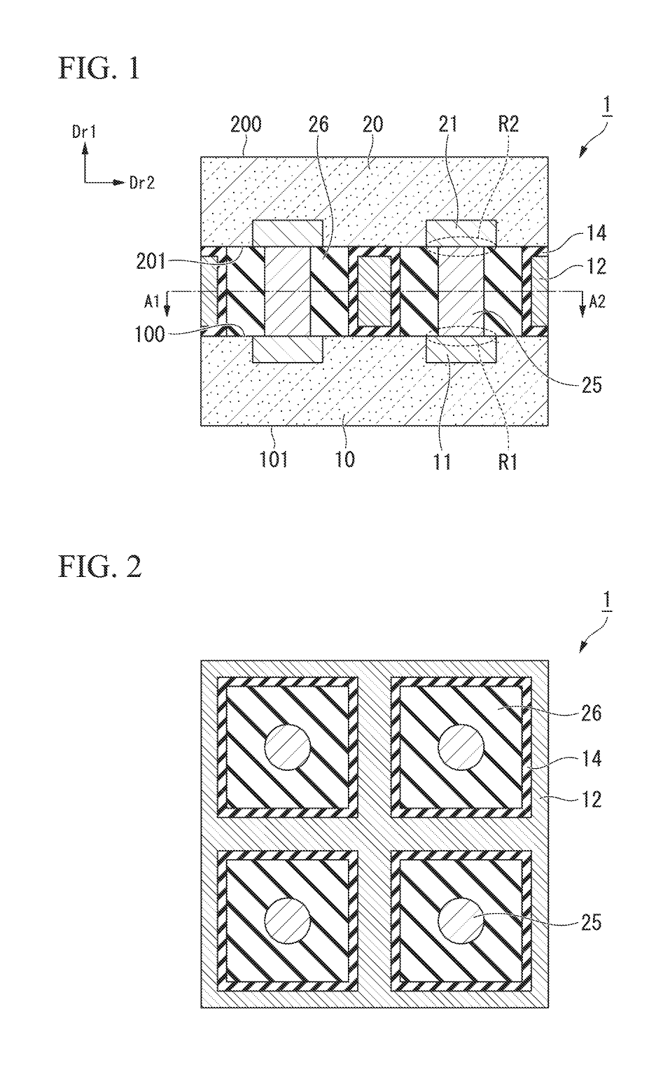

FIG. 1 shows a configuration of a semiconductor device 1 according to a first embodiment of the present invention. FIG. 1 shows a cross section of the semiconductor device 1.

The dimensions of parts which constitute the semiconductor device 1 are not limited to the dimensions shown in FIG. 1. The dimensions of the parts which constitute the semiconductor device 1 are arbitrary. The same applies to dimensions in cross-sectional views other than FIG. 1.

As shown in FIG. 1, the semiconductor device 1 includes a first substrate 10, a second substrate 20, a plurality of connectors 25, a shielding part 12, a first insulating part 14, and a plurality of second insulating parts 26. In FIG. 1, the reference numerals of one connector 25 and one second insulating part 26 are shown as representatives. In the cross section shown in FIG. 1, one shielding part 12 and one first insulating part 14 are composed of a plurality of portions. The first substrate 10 and the second substrate 20 are laminated in a lamination direction Dr1 of the first substrate 10 and the second substrate 20. The lamination direction Dr1 is a direction perpendicular to a plane 100 of the first substrate 10. The lamination direction Dr1 is a thickness direction of the first substrate 10.

The first substrate 10 is formed of a semiconductor material. For example, a semiconductor material forming the first substrate 10 is at least one of silicon (Si) and germanium (Ge). Accordingly, the first substrate 10 is a semiconductor substrate. The first substrate 10 has the plane 100 and a plane 101. The planes 100 and 101 are principal planes of the first substrate 10. The principal planes of the first substrate 10 are relatively large planes among a plurality of planes constituting the surface of the first substrate 10. The plane 100 and the plane 101 face in opposite directions.

The first substrate 10 includes a plurality of first electrodes 11. In FIG. 1, the reference numeral of one first electrode 11 is shown as a representative. The first electrodes 11 are formed of a conductive material (conductor). For example, a conductive material forming the first electrodes 11 is a metal such as gold (Au), silver (Ag) or copper (Cu). The first electrodes 11 are disposed in first regions R1 of the plane 100. The first electrodes 11 are electrically connected to a first circuit included in the first substrate 10.

The second substrate 20 is formed of the same semiconductor material as the first substrate 10. Accordingly, the second substrate 20 is a semiconductor substrate. The second substrate 20 has a plane 200 and a plane 201. The planes 200 and 201 are principal planes of the second substrate 20. The principal planes of the second substrate 20 are relatively large planes among a plurality of planes constituting the surface of the second substrate 20. The plane 200 and the plane 201 face in opposite directions. The plane 100 and the plane 201 face each other.

The second substrate 20 includes a plurality of second electrodes 21. In FIG. 1, the reference numeral of one second electrode 21 is shown as a representative. The second electrodes 21 are formed of the same conductive material as the first electrodes 11. The second electrodes 21 are disposed in second regions R2 of the plane 201. The first regions R1 and the second regions R2 face each other. The second electrodes 21 are electrically connected to a second circuit included in the second substrate 20.

The connectors 25 are formed of a conductive material. For example, a conductive material forming the connectors 25 is a metal such as gold (Au), silver (Ag) or copper (Cu). The connectors 25 are pillar type structures. The connectors 25 are disposed between the first substrate 10 and the second substrate 20. The connectors 25 are disposed in the first regions R1 and the second regions R2. The connectors 25 are connected to the first electrodes 11 and the second electrodes 21. Accordingly, the connectors 25 are connected to the first substrate 10 and the second substrate 20. The connectors 25 electrically connect the first circuit included in the first substrate 10 and the second circuit included in the second substrate 20.

The shielding part 12 is formed of a conductive material. For example, a conductive material forming the shielding part 12 is a metal such as aluminum (Al) or copper (Cu). The first insulating part 14 is formed of an insulating material (insulator). For example, an insulating material forming the first insulating part 14 is silicon oxide (SiO2). The first insulating part 14 is a wall-shaped structure. The shielding part 12 and the first insulating part 14 are disposed between the first substrate 10 and the second substrate 20. The first insulating part 14 comes into contact with the first substrate 10 and the second substrate 20. The first insulating part 14 may come into contact with only the first substrate 10. That is, gaps may be provided between the first insulating part 14 and the second substrate 20. The shielding part 12 is disposed inside of the first insulating part 14 in a cross section perpendicular to the principle planes of the first substrate 10 and the second substrate 20. That is, the first insulating part 14 covers the shielding part 12. The shielding part 12 and the first insulating part 14 are disposed around the connectors 25. The shielding part 12 shields noise. The first insulating part 14 insulates the shielding part 12.

The second insulating parts 26 are cavities (spaces). The second insulating parts 26 are disposed between the first substrate 10 and the second substrate 20. The second insulating parts 26 are disposed between the connectors 25 and the first insulating part 14. The second insulating parts 26 are not filled with a solid. The connectors 25 do not come into contact with the first insulating part 14. The second insulating parts 26 insulate the connectors 25.

FIG. 2 is a cross-sectional view of the semiconductor device 1 including line A1-A2 of FIG. 1. The cross section shown in FIG. 1 and the cross section shown in FIG. 2 are perpendicular to each other. In FIG. 2, the reference numerals of one connector 25, one shielding part 12 and one second insulating part 26 are shown as representatives. The plurality of connectors 25 and the plurality of second insulating parts 26 are arranged in a matrix form. The first insulating part 14 is composed of a plurality of portions in FIG. 2. The plurality of portions of the first insulating part 14 are connected to each other at positions which are not shown. Accordingly, the semiconductor device 1 has a single first insulating part 14 and a single shielding part 12. The shielding part 12, the first insulating part 14 and the second insulating parts 26 are disposed between two neighboring connectors 25.

In FIG. 2, the cross section of the connectors 25 is a circle. The cross section of the connectors 25 may be a polygon. FIG. 2 shows four connectors 25. The number of connectors 25 has only to be two or more.

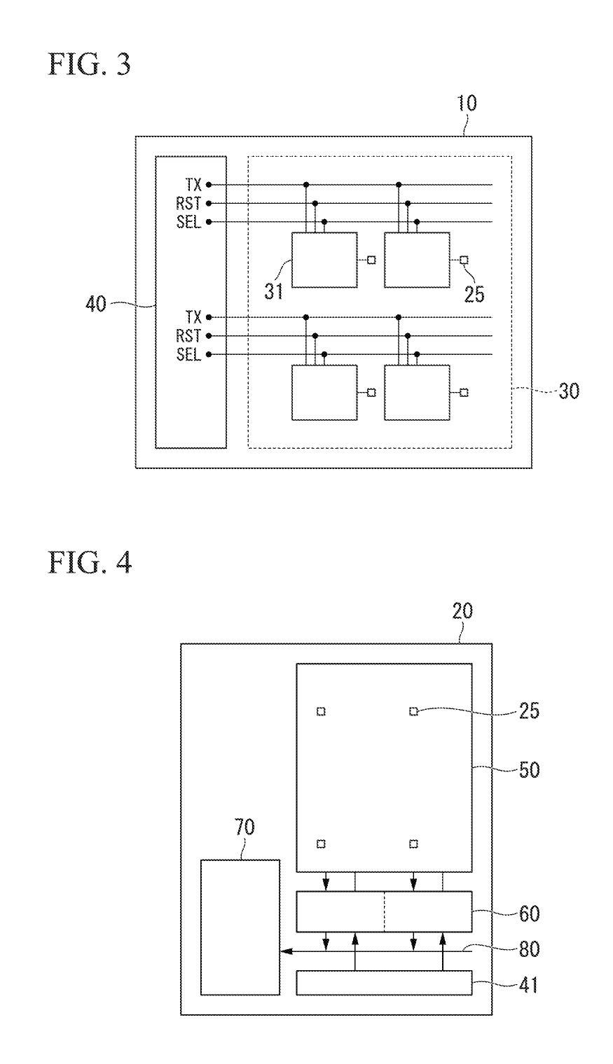

An example in which the semiconductor device 1 is an imager (image sensor) will be described in detail. FIG. 3 shows a configuration of the first substrate 10. As shown in FIG. 3, the first substrate 10 includes a pixel part 30 and a vertical readout circuit 40. FIG. 3 shows positions of the plurality of connectors 25. The sizes of the plurality of connectors 25 are not shown in FIG. 3. In FIG. 3, the reference numeral of one connector 25 is shown as a representative.

The pixel part 30 includes a plurality of pixels 31. In FIG. 3, the reference numeral of one pixel 31 is shown as a representative. The plurality of pixels 31 are arranged in a matrix form. FIG. 3 shows four pixels 31. The number of pixels 31 has only to be two or more. Each pixel 31 includes a photoelectric conversion element, a transfer transistor, a reset transistor, and a select transistor. The photoelectric conversion element generates a pixel signal according to light input to the pixel 31. The transfer transistor reads out the pixel signal from the photoelectric conversion element. The reset transistor resets the pixel 31. The select transistor selects the pixel 31 outputting the pixel signal.

The vertical readout circuit 40 outputs control signals for controlling readout of pixel signals. Accordingly, the vertical readout circuit 40 controls readout of pixel signals from the plurality of pixels 31. The control signals output from the vertical readout circuit 40 are transmitted to the plurality of pixels 31. Pixel signals are simultaneously read out from two or more pixels 31 disposed in the same row in the arrangement of the plurality of pixels 31 according to the control signals.

FIG. 3 shows three control signals. The three control signals include a control signal φTX, a control signal φRST, and a control signal φSEL. The control signal φTX is a signal for controlling the transfer transistors. The control signal φRST is a signal for controlling the reset transistors. The control signal φSEL is a signal for controlling the select transistors.

The plurality of pixels 31 output pixel signals according to the control signals. Each of the plurality of pixels 31 is connected to one connector 25. That is, each of the plurality of connectors 25 is disposed to correspond to each of the plurality of pixels 31. Two or more pixels 31 may be connected to one connector 25. The connectors 25 transmit the pixel signals output from the pixels 31 to the second substrate 20.

The pixels 31 constitute the first circuit disposed on the first substrate 10.

FIG. 4 shows a configuration of the second substrate 20. As shown in FIG. 4, the second substrate 20 includes a horizontal readout circuit 41, a memory unit 50, a signal processing circuit 60, and an output unit 70. Positions of the plurality of connectors 25 are shown in FIG. 4. The sizes of the plurality of connectors 25 are not shown in FIG. 4. In FIG. 4, the reference numeral of one connector 25 is shown as a representative.

The connectors 25 output the pixel signals output from the plurality of pixels 31 to the second substrate 20. The connectors 25 are connected to the memory unit 50. The memory unit 50 stores the pixel signals output from the plurality of pixels 31. The pixel signals stored in the memory unit 50 are output to the signal processing circuit 60. The signal processing circuit 60 performs signal processing on pixel signals according to control of the horizontal readout circuit 41. For example, the signal processing circuit 60 may perform processing such as noise suppression according to correlated double sampling (CDS).

The horizontal readout circuit 41 reads out the pixel signals processed by the signal processing circuit 60 to a horizontal signal line 80. More specifically, the horizontal readout circuit 41 outputs control signals for controlling signal processing of the signal processing circuit 60 and readout of pixel signals to the signal processing circuit 60. According to such control, pixel signals output from two or more pixels 31 disposed in the same row in the arrangement of the plurality of pixels 31 are sequentially read out to the horizontal signal line 80.

The output unit 70 outputs the pixel signals processed by the signal processing circuit 60 to the outside of the semiconductor device 1. More specifically, the output unit 70 performs processing such as amplification processing on the pixel signals processed by the signal processing circuit 60. The output unit 70 outputs the processed pixel signals to the outside of the semiconductor device 1.

The memory unit 50, the signal processing circuit 60, and the output unit 70 constitute the second circuit disposed on the second substrate 20.

As described above, the semiconductor device 1 includes the first substrate 10 (first semiconductor substrate), the second substrate 20 (second semiconductor substrate), the plurality of connectors 25, the first insulating part 14, the shielding part 12, and the second insulating parts 26. The first substrate 10 includes the first circuit. The second substrate 20 is laminated on the first substrate 10 and includes the second circuit. The plurality of connectors 25 are disposed between the first substrate 10 and the second substrate 20 and electrically connect the first circuit and the second circuit. The first insulating part 14 is disposed around each of the plurality of connectors 25. The shielding part 12 is disposed inside of the first insulating part 14 and is formed of a conductor. The second insulating parts 26 are disposed between the connectors 25 and the first insulating part 14.

Positional displacement may occur in the connectors 25 or the first insulating part 14 when the connectors 25 or the first insulating part 14 are formed. Positional displacement between the first substrate 10 and the second substrate 20 may occur when the first substrate 10 and the second substrate 20 are bonded to each other. According to such positional displacement, there is a likelihood of the connectors 25 coming into contact with the first insulating part 14. However, since the shielding part 12 is surrounded by the first insulating part 14, the connectors 25 do not come into contact with the shielding part 12. Accordingly, the likelihood of short-circuiting of the connectors 25 decreases. Since the shielding part 12 is disposed between the first substrate 10 and the second substrate 20, noise which is superimposed on a signal output from the first substrate 10 and is caused by the second circuit disposed on the second substrate 20 is reduced. That is, signal deterioration due to noise is reduced.

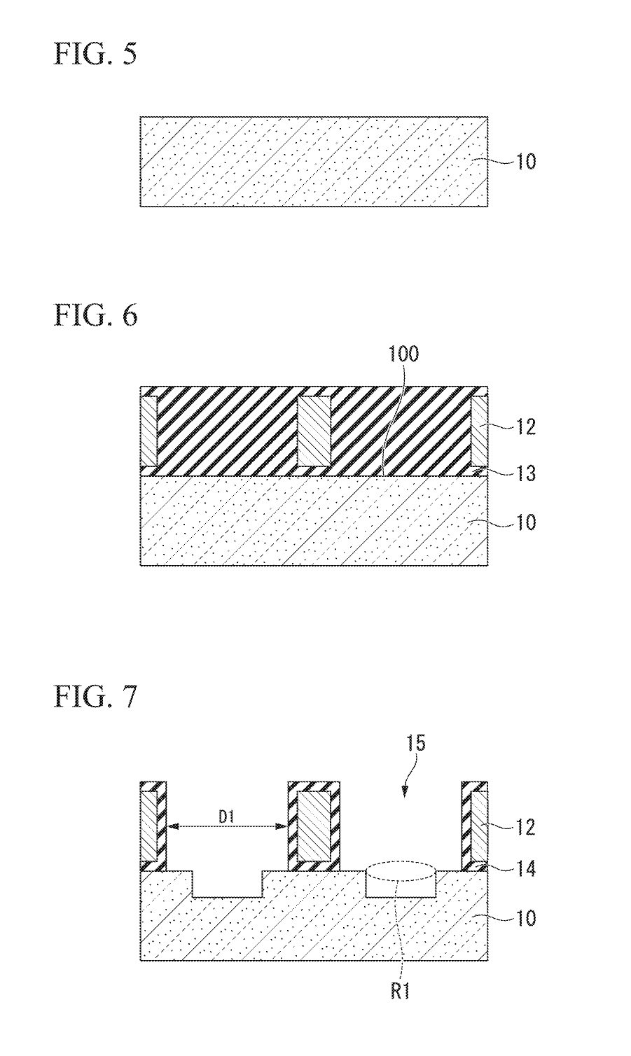

A method of manufacturing the semiconductor device 1 will be described with reference to FIG. 5 to FIG. 13. FIG. 5 to FIG. 13 show cross sections of parts constituting the semiconductor device 1.

### (First Preparation Process)

As shown in FIG. 5, the first substrate 10 is prepared. The first circuit which is not shown is disposed on the first substrate 10. The first circuit is formed through a known semiconductor manufacturing process. After a diffusion layer corresponding to a necessary circuit is formed on the first substrate 10, patterning, etching, formation of vias and formation of wiring are performed. The first circuit is formed by repeating these processes.

### (Process of Forming Shielding Layer 12 and First Insulating Part 14)

As shown in FIG. 6, an insulating layer 13 is formed on the plane 100 of the first substrate 10 and the shielding part 12 is formed inside of the insulating layer 13. Specifically, after an insulating layer is formed on the plane 100, a trench is formed by etching the surface of the insulating layer. For example, the shielding part 12 is formed in the trench through plating. After the surface of the insulating layer is planarized, an insulating material is deposited thereon to form the insulating layer 13.

### (Etching Process)

As shown in FIG. 7, the insulating layer 13 and the first substrate 10 are etched and trenches 15 are formed. Accordingly, the first insulating part 14 is formed. A portion of the insulating layer 13, which remains according to etching, is the first insulating part 14. The trenches 15 include concave parts formed in the first regions R1 of the first substrate 10. That is, the trenches 15 are formed at positions corresponding to the first regions R1. A spacing between neighboring first insulating parts 14 is D1. The spacing D1 is a distance in a direction Dr2 (FIG. 1) perpendicular to the lamination direction Dr1 of the first substrate 10 and the second substrate 20. The direction Dr2 is a direction parallel with the plane 100. The first insulating part 14 is formed around the first regions R1 and the shielding part 12 is formed inside of the first insulating part 14 through the processes shown in FIG. 6 and FIG. 7.

### (Electrode Formation Process)

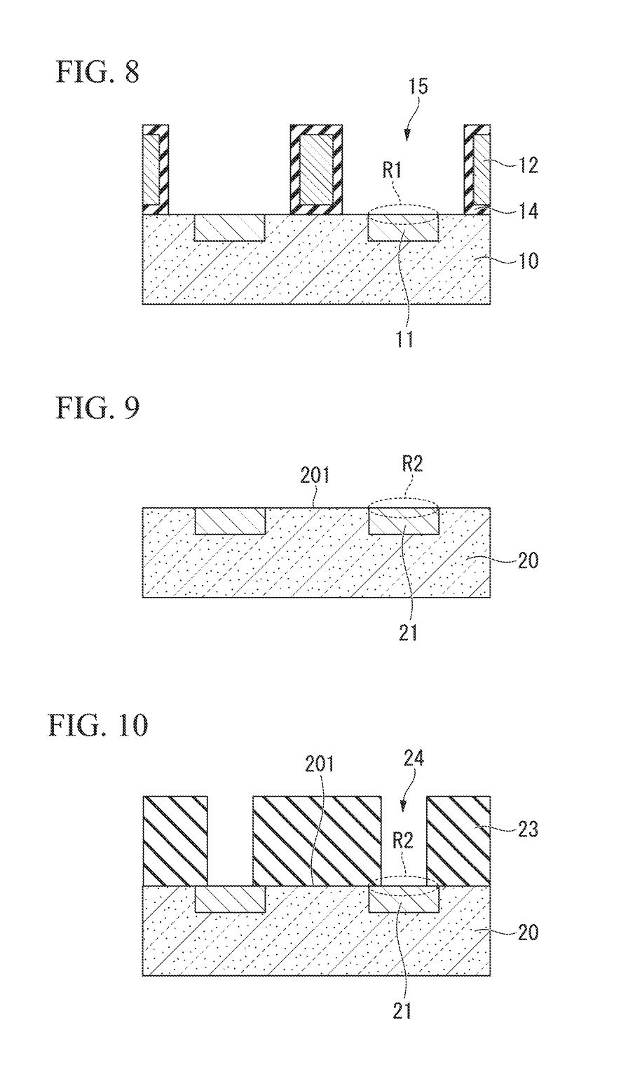

As shown in FIG. 8, the first electrodes 11 are formed in the concave parts of the first regions R1 of the first substrate 10 in the trenches 15. For example, the first electrodes 11 are formed through plating or evaporation.

### (Second Preparation Process)

As shown in FIG. 9, the second substrate 20 on which the second electrodes 21 are formed is prepared. The second circuit which is not shown is disposed on the second substrate 20. A method of forming the second circuit is the same as the method of forming the first circuit of the first substrate 10. The second electrodes 21 are disposed in second regions R2 corresponding to the first regions R1 of the first substrate 10 on the plane 201 of the second substrate 20. A method of forming the second electrodes 21 is the same as the method of forming the first electrodes 11.

### (Resist Formation Process)

As shown in FIG. 10, a resist 23 is formed on the plane 201 of the second substrate 20. In the resist 23, trenches 24 are formed at positions corresponding to the second regions R2 in which the second electrodes 21 are disposed. The trenches 24 are formed by etching the resist 23. That is, portions of the resist 23 which correspond to the second regions R2 are removed.

### (Connector Formation Process)

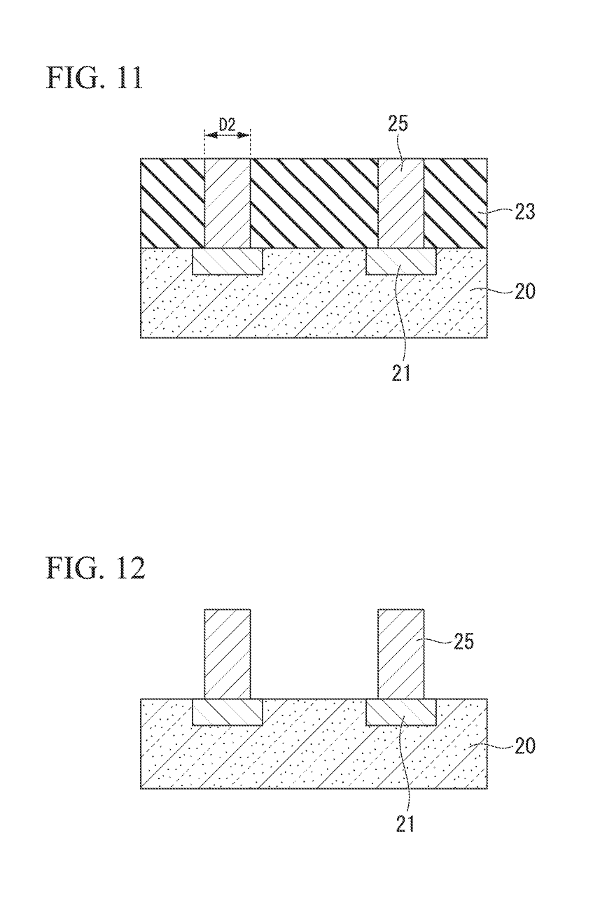

As shown in FIG. 11, the pillar type connectors 25 are formed by filling the trenches 24 with a conductive material. For example, the connectors 25 are formed through plating or evaporation. The thickness of the connectors 25 is D2. The thickness D2 is a width in the direction Dr2 (FIG. 1) perpendicular to the lamination direction Dr1 of the first substrate 10 and the second substrate 20. The thickness D2 is less than the spacing D1.

### (Resist Removal Process)

As shown in FIG. 12, the resist 23 is removed.

### (Bonding Process)

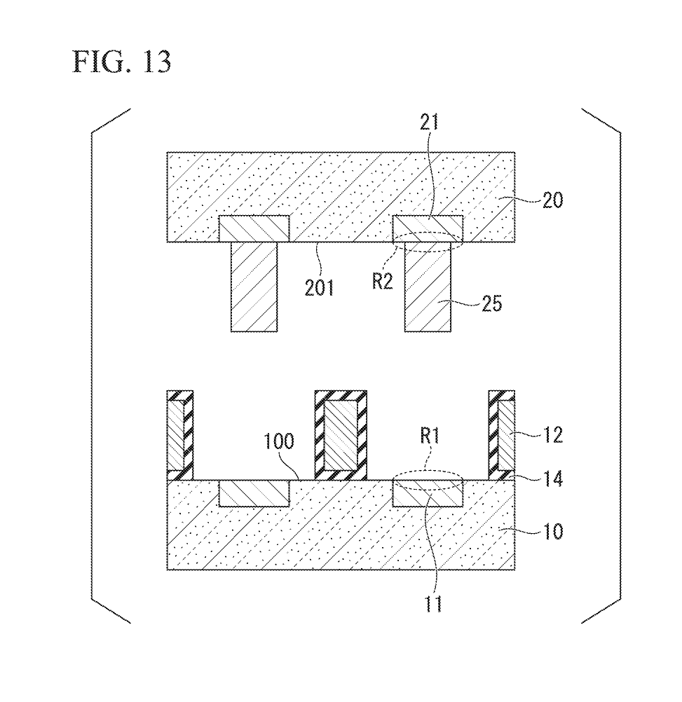

As shown in FIG. 13, the first substrate 10 and the second substrate 20 are bonded. Here, the plane 100 of the first substrate 10 faces the plane 201 of the second substrate 20. Here, the positions of the first substrate 10 and the second substrate 20 are controlled such that the first regions R1 of the first substrate 10 face the second regions R2 of the second substrate 20. For example, the first substrate 10 and the second substrate 20 are bonded through thermal compression. After the first substrate 10 and the second substrate 20 are bonded, the semiconductor device 1 shown in FIG. 1 is completed. The second insulating parts 26 shown in FIG. 1 are formed by bonding the first substrate 10 and the second substrate 20.

As described above, the method of manufacturing the semiconductor device 1 includes a first process (FIG. 6 and FIG. 7), a second process (FIG. 10, FIG. 11 and FIG. 12), and a third process (FIG. 13). The first insulating part 14 is formed around the first regions R1 in which the plurality of connectors 25 are respectively disposed and the shielding part 12 is formed inside of the first insulating part 14 on the plane 100 (first principal plane) of the first substrate 10 through the first process. The first substrate 10 includes the first circuit. The shielding part 12 is formed of a conductor. The plurality of connectors 25 are formed in the second regions R2 corresponding to the first regions R1 on the plane 201 (second principal plane) of the second substrate 20 through the second process. The second substrate 20 includes the second circuit. The first substrate 10 and the second substrate 20 are bonded and a void is provided between the connectors 25 and the first insulating part 14 in a state in which the plane 100 and the plane 201 face each other through the third process. The plurality of connectors 25 electrically connect the first circuit and the second circuit.

A semiconductor device of each embodiment of the present invention need not include a component corresponding to at least one of the first electrodes 11 and the second electrodes 21. The semiconductor device of each embodiment of the present invention need not include circuits other than the first circuit and the second circuit electrically connected to each other through the connectors 25. The semiconductor device of each embodiment of the present invention may be a device other than an imager. A method of manufacturing a semiconductor device of each embodiment of the present invention need not include processes other than the above-described first to third processes.

In the semiconductor device 1 and the method of manufacturing the same according to the first embodiment, the first insulating part 14 is disposed to decrease the likelihood of short-circuiting of the connectors 25. The shielding part 12 is disposed to reduce signal deterioration due to noise.

The shielding part 12 may be electrically insulated from all of the first substrate 10, the second substrate 20, and the plurality of connectors 25. When the shielding part 12 is floating, it is not necessary to form a structure for connecting the shielding part 12 to a fixed potential. Accordingly, the shielding part 12 may be miniaturized. As a result, the spacing of the connectors 25 may be reduced. Therefore, densification of the connectors 25 is realized.

The connectors 25 may be formed of a first material and the shielding part 12 may be formed of a second material different from the first material. That is, the connectors 25 and the shielding part 12 may be formed of different materials. When the shielding part 12 is formed of a material on which fine processing is easily performed, the area occupied by the first insulating part 14 is reduced. Accordingly, densification of the connectors 25 is realized.

Since a void is provided between the connectors 25 and the first insulating part 14, manufacturing costs of the semiconductor device 1 can be decreased as compared to manufacturing costs when a resin is filled into the void. In the semiconductor device 1, separation of the connectors 25 from the first substrate 10 or the second substrate 20 according to expansion of the resin is avoided.

### Modified Example of First Embodiment

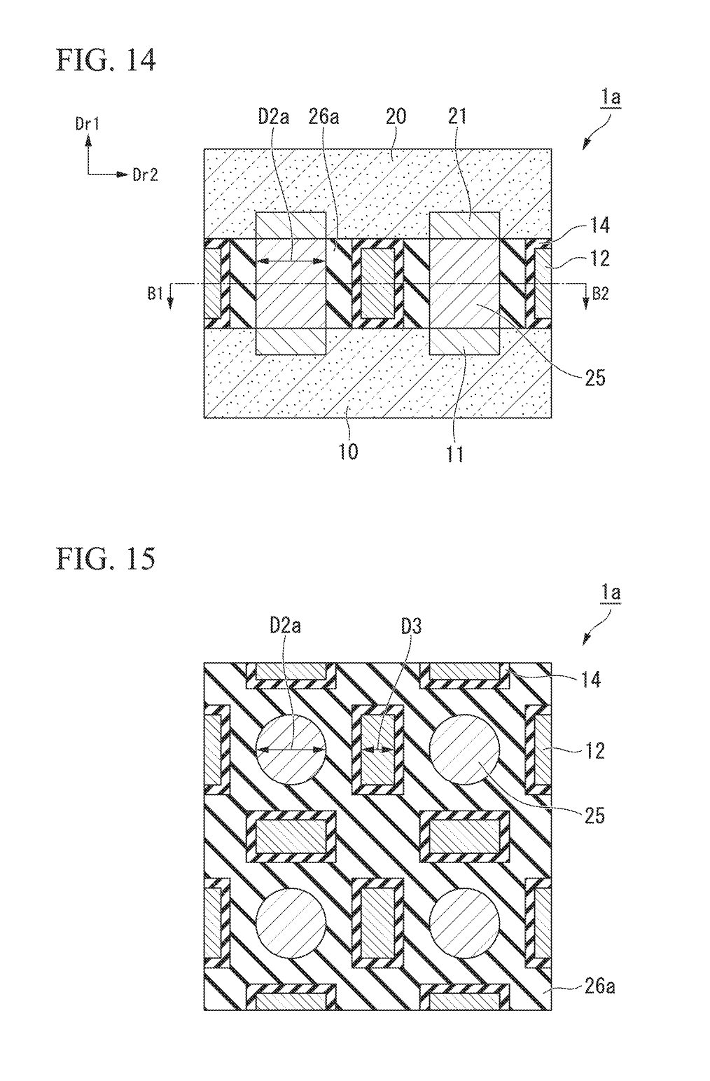

FIG. 14 shows a configuration of a semiconductor device 1a according to a modified example of the first embodiment of the present invention. In FIG. 14, a cross section of the semiconductor device 1a is shown. In FIG. 14, points different from FIG. 1 will be described.

In the semiconductor device 1a, the second insulating parts 26 in the semiconductor device 1 shown in FIG. 1 are changed to a second insulating part 26a. The second insulating part 26a is formed of an insulating material. For example, an insulating material forming the second insulating part 26a is a resin. The second insulating part 26a is disposed between the connectors 25 and the first insulating part 14. The second insulating part 26a comes into contact with the connectors 25 and the first insulating part 14. The connectors 25 do not come into contact with the first insulating part 14. The second insulating part 26a insulates the connectors 25.

The semiconductor device 1a includes a plurality of first insulating parts 14 and a plurality of shielding parts 12. Gaps are provided between the plurality of first insulating parts 14. Gaps are provided between each of the plurality of first insulating parts 14 and each of the plurality of connectors 25. That is, gaps are provided between two neighboring first insulating parts 14. The plurality of first insulating parts 14 are separated from each other. Each of the plurality of first insulating parts 14 and each of the connectors 25 are separated from each other. The second insulating part 26a is disposed in the gaps therebetween. Each of the plurality of shielding parts 12 is disposed inside of one of the plurality of first insulating parts 14.

The thickness of the connectors 25 is D2a. The thickness D2a is a width in the direction Dr2 perpendicular to the lamination direction Dr1 of the first substrate 10 and the second substrate 20. The thickness D2a is greater than the thickness D2 (FIG. 11) of the connectors 25 in the semiconductor device 1 shown in FIG. 1.

With respect to points other than the above, the configuration shown in FIG. 14 is the same as the configuration shown in FIG. 1.

FIG. 15 is a cross-sectional view of the semiconductor device 1a including line B1-B2 of FIG. 14. The cross section shown in FIG. 14 and the cross section shown in FIG. 15 are perpendicular to each other. In FIG. 15, the reference numerals of one connector 25, one shielding part 12, and one first insulating part 14 are shown as representatives. In FIG. 15, points different from FIG. 2 will be described.

Two or more first insulating parts 14 and two or more shielding parts 12 are disposed corresponding to each of the plurality of connectors 25. That is, two or more first insulating parts 14 and two or more shielding parts 12 are disposed around one connector 25. As shown in FIG. 15, four first insulating parts 14 and four shielding parts 12 are disposed around one connector 25. One connector 25 is surrounded by two or more first insulating parts 14 and two or more shielding parts 12.

The thickness D3 of the shielding parts 12 in the direction Dr2 perpendicular to the lamination direction Dr1 of the first substrate 10 and the second substrate 20 is less than the thickness D2a of the connectors 25 in the direction Dr2.

With respect to points other than the above, the configuration shown in FIG. 15 is the same as the configuration shown in FIG. 2.

A method of manufacturing the semiconductor device 1a includes the processes shown in FIG. 5 to FIG. 13 and a resin filling process. Since the processes shown in FIG. 5 to FIG. 13 have been described, description thereof is omitted. The resin filling process will be described with reference to FIG. 14.

### (Resin Filling Process)

A void is provided around the first insulating parts 14 and the connectors 25 through the process shown in FIG. 13. As shown in FIG. 14, a resin is filled into the void to form the second insulating part 26a.

The method of manufacturing the semiconductor device 1a includes a fourth process in addition to the first to third processes. After the first substrate 10 and the second substrate 20 are bonded, an insulating resin is filled into the void in the fourth process.

In the semiconductor device 1a, the thickness D3 of the shielding parts 12 may be equal to or greater than the thickness D2a of the connectors 25. In the semiconductor device 1 shown in FIG. 1, the second insulating parts 26 may be formed of a resin.

The spacing of the connectors 25 may be reduced by causing the thickness D3 of the shielding parts 12 to be less than the thickness D2a of the connectors 25. Accordingly, densification of the connectors 25 is realized. Otherwise, the thickness D2a of the connectors 25 may be increased by causing the thickness D3 of the shielding parts 12 to be less than the thickness D2a of the connectors 25. Accordingly, reliability of connection between the first substrate 10 and the second substrate 20 and the connectors 25 is improved.

The plurality of first insulating parts 14 are disposed to form a resin injection path between the plurality of first insulating parts 14. Since it is difficult for a void to be generated when the resin is filled in, the second insulating part 26a is easily formed.

Since the second insulating part 26a is disposed, separation of the connectors 25 from the first substrate 10 or the second substrate 20 due to an impact applied to the semiconductor device 1a from outside is reduced.

### Second Embodiment

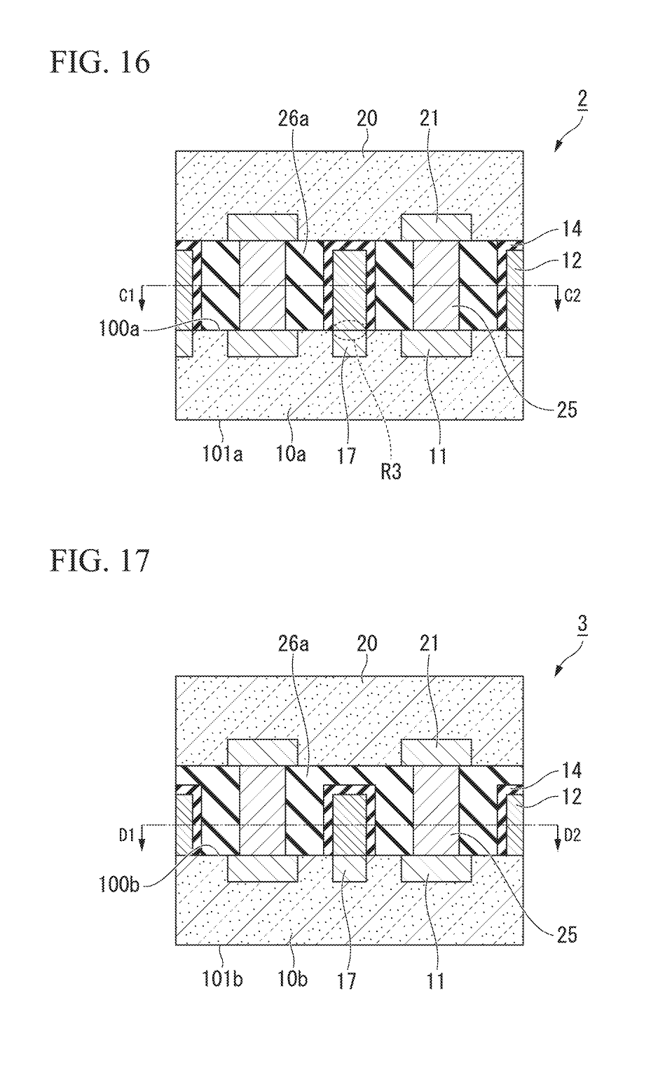

FIG. 16 shows a configuration of a semiconductor device 2 according to a second embodiment of the present invention. In FIG. 16, a cross section of the semiconductor device 2 is shown. In FIG. 16, points different from FIG. 14 will be described.

In the semiconductor device 2, the first substrate 10 in the semiconductor device 1a shown in FIG. 14 is changed to a first substrate 10a. The first substrate 10a is formed of the same semiconductor material as the first substrate 10. The first substrate 10a includes a plane 100a and a plane 101a. The plane 100a and the plane 101a are principal planes of the first substrate 10a. The plane 100a and the plane 101a face in opposite directions.

The first substrate 10a includes a plurality of first electrodes 11 and a plurality of third electrodes 17. In FIG. 16, the reference numeral of one third electrode 17 is shown as a representative. The third electrodes 17 are formed of a conductive material. For example, a conductive material forming the third electrodes 17 is a metal such as gold (Au), silver (Ag) or copper (Cu). The third electrodes 17 are disposed in third regions R3 of the plane 100a. A fixed potential is applied to the third electrodes 17. For example, the fixed potential is a power source or the ground. The third electrodes 17 may be electrically connected to the first circuit included in the first substrate 10a. The third electrodes 17 may have a pad form or a via form.

The shielding part 12 is electrically connected to only any one of the first substrate 10a and the second substrate 20. The shielding part 12 is connected to a fixed potential in the first substrate 10a or the second substrate 20 to which the shielding part 12 is connected.

In the semiconductor device 2 shown in FIG. 16, the shielding part 12 is connected to the third electrodes 17. Accordingly, the shielding part 12 is electrically connected to the first substrate 10a and insulated from the second substrate 20. The shielding part 12 may be electrically connected to the second substrate 20 and insulated from the first substrate 10a.

The thickness of the connectors 25 in FIG. 16 is different from the thickness of the connectors 25 in FIG. 14. However, the thickness of the connectors 25 in FIG. 16 may be the same as the thickness of the connectors 25 in FIG. 14. In the semiconductor device 2, a single first insulating part 14 may be disposed as in the semiconductor device 1 shown in FIG. 1.

With respect to points other than the above, the configuration shown in FIG. 16 is the same as the configuration shown in FIG. 14. A cross section of the semiconductor device 2 including line C1-C2 of FIG. 16 is the same as the cross section of the semiconductor device 1a shown in FIG. 15.

The shielding part 12 is connected to a fixed potential and thus a shielding effect with respect to noise is improved.

### Third Embodiment

FIG. 17 shows a configuration of a semiconductor device 3 according to a third embodiment of the present invention. In FIG. 17, a cross section of the semiconductor device 3 is shown. In FIG. 17, points different from FIG. 16 will be described.

In the semiconductor device 3, the first substrate 10a in the semiconductor device 2 shown in FIG. 16 is changed to a first substrate 10b. The first substrate 10b is formed of the same semiconductor material as the first substrate 10a. The first substrate 10b includes a plane 100b and a plane 101b. The plane 100b and the plane 101b are principal planes of the first substrate 10b. The plane 100b and the plane 101b face in opposite directions.

The first substrate 10a in the semiconductor device 2 shown in FIG. 16 includes a plurality of third electrodes 17, whereas the first substrate 10b in the semiconductor device 3 shown in FIG. 17 includes a single third electrode 17. Like the semiconductor device 1 shown in FIG. 1, the semiconductor device 3 includes a single shielding part 12. The shielding part 12 is connected to the single third electrode 17.

The shielding part 12 is electrically connected to only any one of the first substrate 10b and the second substrate 20. Gaps are provided between a semiconductor substrate different from a semiconductor substrate connected to the shielding part 12, among the first substrate 10b and the second substrate 20, and the first insulating part 14.

In the semiconductor device 3 shown in FIG. 17, the shielding part 12 is connected to the third electrode 17. Accordingly, the shielding part 12 is electrically connected to the first substrate 10b and insulated from the second substrate 20. Gaps are provided between the second substrate 20 and the first insulating part 14. A second insulating part 26a is disposed in the gaps. The shielding part 12 may be electrically connected to the second substrate 20 and insulated from the first substrate 10b. Gaps may be provided between the first substrate 10b and the first insulating part 14.

With respect to points other than the above, the configuration shown in FIG. 17 is the same as the configuration shown in FIG. 16. A cross section of the semiconductor device 3 including line D1-D2 of FIG. 17 is the same as the cross section of the semiconductor device 1 shown in FIG. 2.

The gaps between the first insulating part 14 and the second substrate 20 become a resin injection path. Accordingly, a plurality of first insulating parts 14 need not be disposed. When the shielding part 12 is connected to a fixed potential, a plurality of third electrodes 17 need not be disposed. Accordingly, it is possible to reduce the spacing of the first electrodes 11, that is, the spacing of the connectors 25. Therefore, densification of the connectors 25 is realized.

While preferred embodiments of the invention have been described and shown above, it should be understood that these are exemplars of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A semiconductor device comprising:
a first semiconductor substrate including a first circuit;
a second semiconductor substrate that is laminated on the first semiconductor substrate and includes a second circuit;
a plurality of connectors that are disposed between the first semiconductor substrate and the second semiconductor substrate and electrically connect the first circuit and the second circuit;
a first insulating part disposed around each of connectors included in the plurality of connectors; and
a shielding part disposed inside of the first insulating part and formed of a conductor,
wherein a void is provided between the connectors and the first insulating part.

2. The semiconductor device according to claim 1, wherein the shielding part is electrically insulated from all of the first semiconductor substrate, the second semiconductor substrate and the plurality of connectors.

3. The semiconductor device according to claim 1, wherein the shielding part is electrically connected to only any one of the first semiconductor substrate and the second semiconductor substrate, and
the shielding part is connected to a fixed potential in the first semiconductor substrate or the second semiconductor substrate to which the shielding part is connected.

4. The semiconductor device according to claim 1, further comprising a plurality of first insulating parts including the first insulating part and comprising a plurality of shielding parts including the shielding part,
wherein gaps are provided between the plurality of first insulating parts, and
gaps are provided between each of first insulating parts included in the plurality of first insulating parts and each of the connectors.

5. The semiconductor device according to claim 4, wherein two or more of the first insulating parts and two or more of the shielding parts are disposed corresponding to each of the connectors.

6. The semiconductor device according to claim 1, wherein the shielding part is electrically connected to only the first semiconductor substrate, and
gaps are provided between the second semiconductor substrate and the first insulating part.

7. The semiconductor device according to claim 1, wherein the connectors are formed of a first material, and
the shielding part is formed of a second material different from the first material.

8. The semiconductor device according to claim 1, wherein the thickness of the shielding part in a direction perpendicular to a lamination direction of the first semiconductor substrate and the second semiconductor substrate is less than the thickness of the connectors in the direction.

9. A method of manufacturing a semiconductor device, comprising:
a first process of forming a first insulating part around a first region in which each of a plurality of connectors are to be disposed on a first principal plane of a first semiconductor substrate and forming a shielding part inside of the first insulating part, the first semiconductor substrate including a first circuit, the shielding part being formed of a conductor;
a second process of forming the plurality of connectors in a second region corresponding to the first region on a second principal plane of a second semiconductor substrate, the second semiconductor substrate including a second circuit;
a third process of bonding the first semiconductor substrate and the second semiconductor substrate in a state in which the first principal plane and the second principal plane face each other, and providing a void between connectors included in the plurality of connectors and the first insulating part, the plurality of connectors electrically connecting the first circuit and the second circuit.

10. The method of manufacturing a semiconductor device according to claim 9, further comprising a fourth process of filling the void with an insulating resin after the first semiconductor substrate and the second semiconductor substrate are bonded.
